(19) United States
(12) Patent Application Publication
(10) Pub. No.: US 2026/0257246 A1
(43) Pub. Date: Sep. 3, 2026

(54) SUBSTRATE CLEANING SYSTEM

(71) Applicant: KCTECH CO., LTD., Gyeonggi-do (KR)

(72) Inventors: GEUN SIK YUN, Gyeonggi-do (KR); TAE HYUNG KIM, Gyeonggi-do (KR)

(73) Assignee: KCTECH CO., LTD., Gyeonggi-do (KR)

(21) Appl. No.: 19/455,868

(22) Filed: Jan. 22, 2026

(30) Foreign Application Priority Data
Feb. 28, 2025 (KR) 10-2025-0026396

(51) Int. Cl. B08B 1/12; B08B 1/34

(52) U.S. Cl. CPC B08B 1/12; B08B 1/34

(57) ABSTRACT

A substrate cleaning system includes a base, a plurality of support structures, a plurality of support frames including a frame body and a guide rail formed on the frame body in a height direction, a plurality of upper brackets, a plurality of lower brackets, an upper brush connected to the plurality of upper brackets to be rotatable about a first rotation axis parallel to the first axis, and configured to clean an upper surface of a substrate, a lower brush connected to the plurality of lower brackets to be rotatable about a second rotation axis parallel to the first axis, and configured to clean a lower surface of the substrate, a rotation actuator, an upper load cell, an upper stopper connected to a frame body of a support frame to position in a lower portion of the upper load cell, a lower load cell, and a hinge portion.

### CROSS-REFERENCE TO RELATED APPLICATION

This application claims the benefit of Korean Patent Application No. 10-2025-0026396, filed on Feb. 28, 2025, in the Korean Intellectual Property Office, the entire disclosure of which is incorporated herein by reference for all purposes.

### BACKGROUND

### 1. Field of the Invention

One or more embodiments relate to a substrate cleaning system.

### 2. Description of the Related Art

In general, semiconductors are manufactured by repeatedly performing a series of processes such as lithography, deposition, and etching. Contaminants such as various particles, metal impurities, or organic materials remain on a surface of a substrate constituting a semiconductor by repeated processes. Due to such contaminants remaining on the substrate, the reliability of the semiconductor may decrease. To resolve this issue, a process of cleaning or buffing a substrate is required in a manufacturing process of a semiconductor. The substrate cleaning process may be performed by a brush, and research and development have been continuously conducted to control the pressure of the brush on the substrate during the substrate cleaning process and to prevent or reduce the tilting phenomenon in which the brush tilts left and right.

However, the foregoing description should not be construed as having been acknowledged by the applicant as a prior art to the description set forth in the disclosure but should be construed only as a related art to the invention described herein.

### SUMMARY

Embodiments provide a substrate cleaning system including an upper load cell and an upper stopper for controlling the pressure of a brush.

Embodiments provide a substrate cleaning system including a hinge portion, a lower load cell, and a lower stopper for preventing or reducing the tilting phenomenon of a brush.

An aspect of a substrate cleaning system according to an embodiment is not limited to the above-mentioned effects, and other unmentioned effects can be clearly understood from the following description by one of ordinary skill in the art.

According to an aspect, there is provided a substrate cleaning system including a base, a plurality of support structures arranged in parallel with each other on the base, a plurality of support frames connected to each of the plurality of support structures to be rotatable about a first axis and including a frame body and a guide rail formed on the frame body in a height direction, a plurality of upper brackets connected to each of the plurality of support frames to be movable in the height direction along the guide rail, a plurality of lower brackets arranged in a lower portion of the plurality of upper brackets, and connected to each of the plurality of support frames to be movable in the height direction along the guide rail, an upper brush connected to the plurality of upper brackets to be rotatable about a first rotation axis parallel to the first axis, and configured to clean an upper surface of a substrate, a lower brush connected to the plurality of lower brackets to be rotatable about a second rotation axis parallel to the first axis, and configured to clean a lower surface of the substrate, a rotation actuator connected to the upper brush and the lower brush, an upper load cell connected to an upper bracket, an upper stopper connected to a frame body of a support frame to be positioned below the upper load cell, a lower load cell arranged on the base, and a hinge portion connected to the frame body of the support frame and configured to press the lower load cell when the support frame rotates in a first rotation direction.

The upper load cell may be configured to contact the upper stopper and detect pressing force applied by the upper stopper when an upper bracket moves downward on the guide rail along the height direction.

The substrate cleaning system may further include a controller, wherein the controller may be configured to, based on information regarding the detected pressing force of the upper load cell, move the upper bracket and a lower bracket away from each other when the pressing force is greater than a set range, and move the upper bracket and the lower bracket toward each other when the pressing force is less than the set range.

The substrate cleaning system may further include a lower stopper arranged in the base so that the lower stopper is configured to contact the hinge portion when the support frame rotates in a second rotation direction, which is opposite to the first rotation direction.

The hinge portion may include a hinge body connected to the frame body, a first flange extending from the hinge body and configured to press the lower load cell, and a second flange extending from the hinge body and configured to press the lower stopper.

The lower load cell may be configured to detect pressing force applied by the first flange of the hinge portion when the support frame rotates in the first rotation direction.

The substrate cleaning system may further include a torque detection portion configured to detect a rotation torque of the rotation actuator, and a controller, wherein the controller may be configured to detect frictional force between the substrate and the lower brush based on information regarding the pressing force detected by the lower load cell and information regarding the rotation torque detected by the torque detection portion, and control an operation of the rotation actuator based on information regarding the detected frictional force.

The upper bracket may include a first upper bracket portion connected to the upper brush, a second upper bracket portion extending from the first upper bracket portion and connected to the support frame, and a third upper bracket portion extending from the second upper bracket portion and connected to the upper load cell.

The lower bracket may include a first lower bracket portion connected to the lower brush and a second lower bracket portion extending from the first lower bracket and connected to the support frame.

Additional aspects of embodiments will be set forth in part in the description which follows and, in part, will be apparent from the description, or may be learned by practice of the disclosure.

According to embodiments, a substrate cleaning system may detect the pressure of a brush on a substrate through an upper load cell and an upper stopper and may feedback-control the pressure of the brush based on information regarding the detected pressure of the brush.

According to embodiments, a substrate cleaning system may prevent or reduce the tilting phenomenon, in which the left-right gradient of the brush changes, through a hinge portion, a lower load cell, and a lower stopper.

According to embodiments, a substrate cleaning system may detect friction between a substrate and a brush by comparing pressing force of a hinge portion detected by a lower load cell to a rotation torque of a rotation actuator that rotates the brush to analyze frictional characteristics between the brush and the surface of the substrate and increase the efficiency of a substrate cleaning process based on the analyzed frictional characteristics.

The effects of a substrate cleaning system according to an embodiment are not limited to the above-mentioned effects, and other unmentioned effects can be clearly understood from the following description by one of ordinary skill in the art.

### BRIEF DESCRIPTION OF THE DRAWINGS

The accompanying drawings illustrate desired embodiments of the present disclosure and are provided together with the detailed description for better understanding of the technical idea of the present disclosure. Therefore, the present disclosure should not be construed as being limited to the embodiments set forth in the drawings.

These and/or other aspects, features, and advantages of the invention will become apparent and more readily appreciated from the following description of embodiments, taken in conjunction with the accompanying drawings of which:

FIG. 1 is a perspective view of a substrate cleaning system according to an embodiment;

FIG. 2 is a diagram illustrating an aspect of a substrate cleaning system, in order to show an upper load cell, an upper stopper, a lower load cell, a lower stopper, and a hinge portion of a substrate cleaning system according to an embodiment in detail;

FIG. 3 is a front view of a substrate cleaning system according to an embodiment;

FIG. 4 is a right side view of a substrate cleaning system according to an embodiment; and

FIG. 5 is a left side view of a substrate cleaning system according to an embodiment.

### DETAILED DESCRIPTION

Hereinafter, embodiments are described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not intended to limit the embodiments. The singular forms “a,” “an,” and “the” are intended to include the plural forms as well, unless the context clearly indicates otherwise. It should be further understood that the terms “comprises/comprising” and/or “includes/including,” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical or scientific terms used herein have the same meaning as those commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto is omitted. In the description of embodiments, detailed description of well-known related structures or functions is omitted when it is deemed that such description may cause ambiguous interpretation of the present disclosure. It is to be understood that a singular form of a noun corresponding to an item may include one or more of the things unless the relevant context clearly indicates otherwise. As used herein, each of phrases such as “A or B,” “at least one of A and B,” “at least one of A or B,” “A, B, or C,” “at least one of A, B, and C,” and “at least one of A, B, or C” may include any one of the items listed in the corresponding one of the phrases or all possible combinations thereof.

Also, in the description of the components of the embodiments, terms such as first, second, A, B, (a), (b), and the like may be used. These terms are used only for the purpose of discriminating one component from another component, and the nature, the sequences, the orders, or the like of the components are not limited by the terms. It is to be understood that when a component is described as being “connected,” “coupled,” or “joined” to another component, the former may be directly “connected,” “coupled,” or “joined” to the latter or “connected,” “coupled,” or “joined” to the latter via another component.

As used herein, the terms “substantially,” “approximately,” “generally,” and “about” in reference to a given parameter, attribute, or condition may include a degree that one of ordinary skill in the art would understand that the given parameter, attribute, or condition is met with a small degree of variance, such as within acceptable manufacturing tolerances. For example, a parameter that is substantially met may be at least 90% met, at least 95% met, or at least 99% met.

The same name may be used to describe components having the same function, which are included in different embodiments. Unless otherwise mentioned, the description of one embodiment may be applicable to another embodiment. Thus, duplicated description is omitted for conciseness.

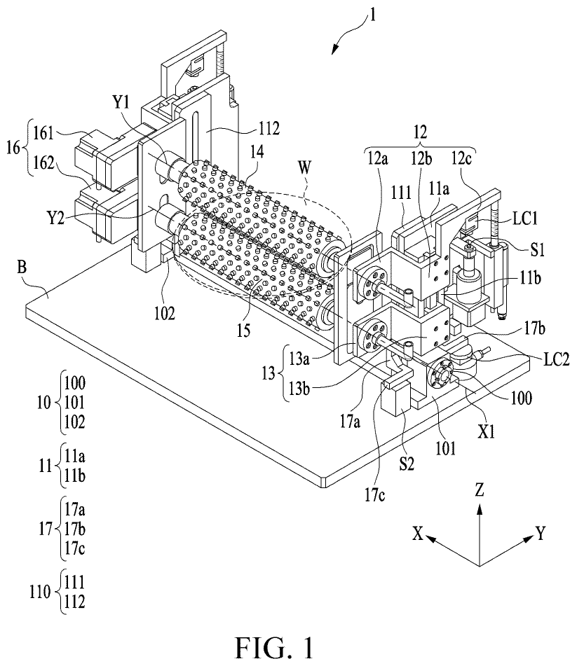

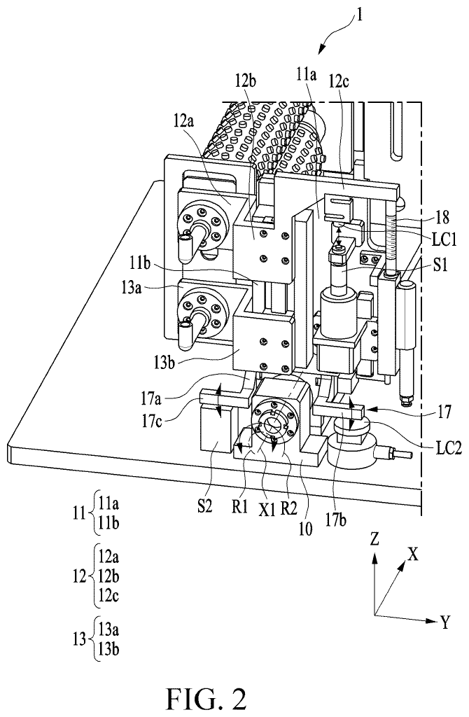

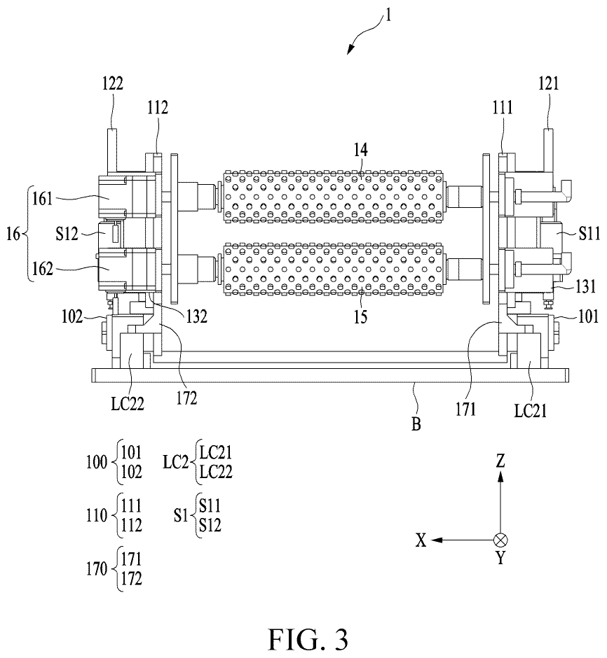

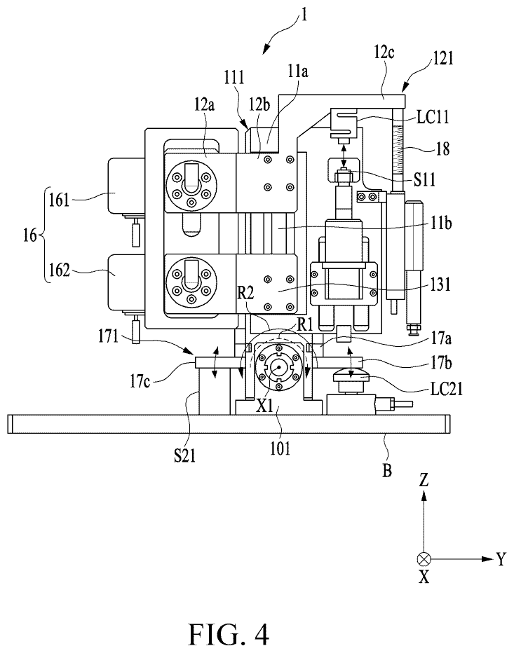

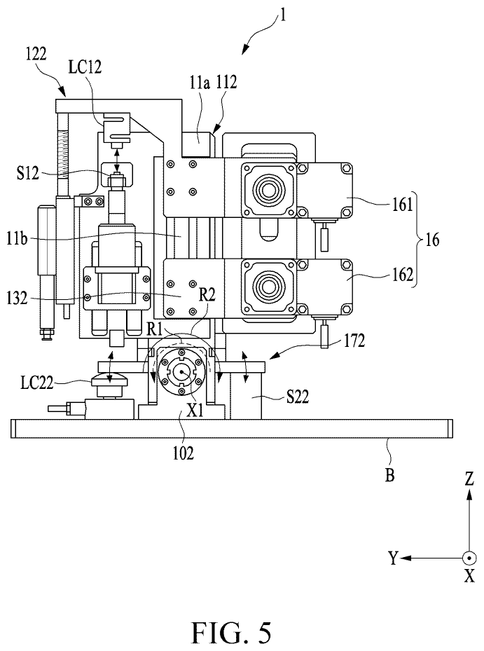

FIG. 1 is a perspective view of a substrate cleaning system according to an embodiment. FIG. 2 is a diagram illustrating an aspect of a substrate cleaning system, in order to show an upper load cell, an upper stopper, a lower load cell, a lower stopper, and a hinge portion of a substrate cleaning system according to an embodiment in detail. FIG. 3 is a front view of a substrate cleaning system according to an embodiment. FIG. 4 is a right side view of a substrate cleaning system according to an embodiment. FIG. 5 is a left side view of a substrate cleaning system according to an embodiment. Hereinafter, in the description of a substrate cleaning system, the right side may refer to a −X-axis direction and the left side may refer to a +X-axis direction based on the direction illustrated in the drawings, unless otherwise specified. In addition, it may be construed that an upper portion or an upper side refers to a +Z-axis direction and a lower portion or a lower side refers to a −Z-axis direction.

Referring to FIGS. 1 to 5, a substrate cleaning system 1 may clean a substrate W. For example, the substrate cleaning system 1 may clean the substrate W, specifically a surface of the substrate W, which has been cleaned, buffed, or polished. The substrate cleaning system 1 may support the substrate W. The substrate cleaning system 1 may clean the supported substrate W through a plurality of brushes. In an embodiment, the substrate cleaning system 1 may include a base B, a plurality of support structures 10, a plurality of support frames 11, a plurality of upper brackets 12, a plurality of lower brackets 13, an upper brush 14, a lower brush 15, a rotation actuator 16, an upper load cell LC1, an upper stopper S1, a lower load cell LC2, a lower stopper S2, a hinge portion 17, a controller, a torque detection portion, and/or a displacement sensor 18.

In an embodiment, the base B may form a lower portion of the substrate cleaning system 1. The base B may be a member in contact with a ground or the ground itself. That is, a shape of the base B is not defined as one particular object but may be formed in any shape in which other components of the substrate cleaning system 1 described below may be arranged or supported. The base B may be arranged on the ground to support other components (e.g., the plurality of support structures 10) of the substrate cleaning system 1.

In an embodiment, the plurality of support structures 10 may be arranged on the base B. The support structures 10 may be provided as a plurality of support structures (e.g., the plurality of support structures 101 and 102 of FIG. 1) arranged on the base B. The support structures 10 may be disposed on the base B to face each other in a parallel direction (e.g., a direction parallel to the X-axis). Each of the support structures 10 may include a hinge bearing 100 provided to be rotatable about a first axis X1. The support frame 11 described below may be rotatably connected to the hinge bearing 100. While two support structures 10 are illustrated in the drawings, the number of the support structures 10 is not limited thereto. Hereinafter, the number of the support structures 10 is assumed to be two.

In an embodiment, the support frame 11 may be rotatably connected to the support structures 10 arranged on the base B. The support frame 11 may be provided in plurality (e.g., a support frame 111 and a support frame 112 of FIG. 3). Each of the plurality of support frames 11 may be rotatably connected to each of the support structures 10. Each of the plurality of support frames 11 may rotate about the first axis X1. Each of the support frames 11 may support other components (e.g., the upper bracket 12 and/or the lower bracket 13) of the substrate cleaning system 1 described below. In an embodiment, the support frame 11 may include a frame body 11a and a guide rail 11b. The frame body 11a may be a portion corresponding to a body of the support frame 11. The guide rail 11b may be formed on the frame body 11a. The guide rail 11b may form a movement path along which the upper bracket 12 and/or the lower bracket 13 described below may move up and down in a height direction (e.g., the Z-axis direction). In an embodiment, the number of the support frames 11 is illustrated as two but is not limited thereto. When the number of the support structures 10 exceeds two, the support frames 11 may be provided in the same number as the number of the support structures 10.

In an embodiment, the upper bracket 12 may be connected to the support frame 11. The upper bracket 12 may be provided in plurality. For example, each of the plurality of upper brackets 12 (e.g., an upper bracket 121 and an upper bracket 122) may be connected to each of the plurality of support frames 11 (e.g., the support frame 111 and the support frame 112). That is, one upper bracket 12 may be connected to one support frame 11. The upper bracket 12 may be, when compared to the lower bracket 13 described below, positioned higher than the lower bracket 13. The upper bracket 12 may be connected to the support frame 11 to be movable in a height direction of the support frame 11 along the guide rail 11b formed on the support frame 11. The upper bracket 12 may include a first upper bracket portion 12a, a second upper bracket portion 12b, and a third upper bracket portion 12c. The upper brush 14 described below may be connected to the first upper bracket portion 12a. The support frame 11 may be connected to the second upper bracket portion 12b. The upper load cell LC1 described below may be connected to the third upper bracket portion 12c. The second upper bracket portion 12b may extend from one end of the first upper bracket portion 12a, and the third upper bracket portion 12c may extend from one end of the second upper bracket portion 12b. For example, the second upper bracket portion 12b may be positioned to extend from the first upper bracket portion 12a in a first direction (e.g., the −X-axis direction). The third upper bracket portion 12c may be positioned to extend from the second upper bracket portion 12b in a second direction (e.g., the +Z-axis direction) that is different from the first direction. The extension directions of the first upper bracket portion 12a, the second upper bracket portion 12b, and the third upper bracket portion 12c may be in the first and second directions, different from each other, thereby increasing space utilization. In addition, by extending in different directions, interference between the first upper bracket portion 12a, the second upper bracket portion 12b, and the third upper bracket portion 12c may be prevented or reduced while moving in the height direction of the support frame 11.

In an embodiment, the lower bracket 13 may be connected to the support frame 11. The lower brackets 13 may be provided in plurality. For example, referring to FIG. 3, each of the plurality of lower brackets 13 (e.g., a lower bracket 131 and a lower bracket 132) may be connected to each of the plurality of support frames 11 (e.g., the support frame 111 and the support frame 112). That is, one lower bracket 13 may be connected to one support frame 11. The lower bracket 13 may be positioned lower than the upper bracket 12 on the support frame 11. The lower bracket 13 may be connected to the support frame 11 to be movable in the height direction along the guide rail 11b of the support frame 11. The lower bracket 13 may include a first lower bracket portion 13a and a second lower bracket portion 13b. The lower brush 15 described below may be connected to the first lower bracket portion 13a. The support frame 11 may be connected to the second lower bracket portion 13b. The second lower bracket portion 13b may extend from one end of the first lower bracket portion 13a. For example, the second lower bracket portion 13b may be positioned to extend from the first lower bracket portion 13a in the first direction (e.g., the −X axis direction). In an embodiment, the upper bracket 12 and the lower bracket 13 connected to one support frame 11 may be positioned parallel to each other in the height direction. For example, the first upper bracket portion 12a of the upper bracket 12 and the first lower bracket portion 13a of the lower bracket 13 may be positioned parallel to each other in the height direction (e.g., the Z-axis direction), and the second upper bracket portion 12b and the second lower bracket portion 13b may be positioned parallel to each other in the height direction.

In an embodiment, the upper brush 14 may be arranged to contact a surface of the substrate W, specifically an upper surface of the substrate W (e.g., the surface of the substrate W facing the +Z-axis direction), to clean the surface of the substrate W. The upper brush 14 may be connected to the upper bracket 12 to be rotatable about a first rotation axis Y1. The upper brush 14 connected to the upper bracket 12 may be arranged to be movable in the height direction together with the upper bracket 12 during a process in which the upper bracket 12 moves in the height direction along the guide rail 11b. The first rotation axis Y1 of the upper brush 14 may be parallel to the first axis X1 of the support frame 11.

In an embodiment, the lower brush 15 may be arranged to contact a lower surface of the substrate W (e.g., the surface of the substrate W facing the −Z-axis direction) to clean the surface of the substrate W. The lower brush 15 may be connected to the lower bracket 13 to be rotatable about a second rotation axis Y2. The lower brush 15 connected to the lower bracket 13 may be arranged to be movable in the height direction together with the lower bracket 13 during a process in which the lower bracket 13 moves in the height direction along the guide rail 11b. The lower brush 15 may be arranged parallel to the upper brush 14 with the substrate W interposed therebetween. The upper brush 14 and the lower brush 15 arranged parallel to each other may press a same area of the surface of the substrate W when viewed in the height direction, so pressing forces thereof may be offset from each other, thereby preventing or reducing tilting of the surface of the substrate W.

In an embodiment, the rotation actuator 16 may be connected to the upper brush 14 and the lower brush 15 and may provide rotational power to each of the upper brush 14 and the lower brush 15. For example, the rotation actuator 16 may generate rotational power and transmit the rotational power to the upper brush 14 and the lower brush 15. The upper brush 14 and the lower brush 15, provided with power by the rotation actuator 16, may rotate in the same direction and clean the surface of the substrate W. The rotation actuator 16 is illustrated as separate components in the drawings, including a first rotation actuator 161 connected to the upper brush 14 and a second rotation actuator 162 connected to the lower brush 15. However, the rotation actuator 16 may be a single component. For example, the first rotation actuator 161 and the second rotation actuator 162 may be formed integrally, and the single rotation actuator 16 may be connected to both the upper brush 14 and the lower brush 15. The amount of rotation torque generated by the first rotation actuator 161 may generally be the same as the amount of rotation torque generated by the second rotation actuator 162. However, the amount of rotation torque may vary as needed through a feedback control by the controller described below.

Hereinafter, a mechanism for detecting pressing force of a brush applied to the substrate W by the upper load cell LC1 and the upper stopper S1 is described.

In an embodiment, the upper load cell LC1 may be connected to the upper bracket 12. The upper load cell LC1 may be provided in plurality. For example, each of the plurality of upper load cells LC1 (e.g., an upper load cell LC11 and an upper load cell LC12) may be connected to each of the plurality of upper brackets 12 (e.g., the upper bracket 121 and the upper bracket 122). The upper load cell LC1 may be connected to the third upper bracket portion 12c of the upper bracket 12. In a process in which the upper brush 14 and the lower brush 15 each approach the surface of the substrate W to clean the surface of the substrate W, the upper brush 14 and the lower brush 15 may lightly press the surface of the substrate W. In this process, the upper bracket 12 may move together with the upper brush 14, and the lower bracket 13 may move together with the lower brush 15. That is, the upper bracket 12 may move downward (e.g., in the −Z-axis direction) in the height direction of the support frame 11 (e.g., in the Z-axis direction of FIG. 1) during a cleaning process of the substrate W. When the upper bracket 12 moves downward, the upper load cell LC1 connected to the upper bracket 12 may also move downward together with the upper bracket 12.

In an embodiment, the upper stopper S1 may be connected to the frame body 11a of the support frame 11 to be positioned below the upper load cell LC1. The upper stopper S1 may be provided in plurality. For example, each of the plurality of upper stoppers S1 (e.g., an upper stopper S11 and an upper stopper S12) may be connected to the frame body 11a of each of the plurality of support frames 11 (e.g., the support frame 111 and the support frame 112). The upper stopper S1 may restrict a downward movement of the upper load cell LC1 moving downward together with the upper bracket 12. The upper stopper S1 may be configured to contact the upper load cell LC1 moving downward. In an embodiment, the upper load cell LC1 may detect pressing force applied by the upper stopper S1 when contacting the upper stopper S1. Information regarding the pressing force detected by the upper load cell LC1 may be transferred to the controller described below.

In an embodiment, the controller (not shown) may feedback-control a distance in the height direction (e.g., a distance in the Z-axis direction) between the upper bracket 12 and the lower bracket 13 based on information regarding the detected pressing force of the upper load cell LC1. For example, when the detected pressing force of the upper load cell LC1 is greater than a set range, the controller may move the upper bracket 12 and the lower bracket 13 away from each other, i.e., move the upper bracket 12 upward (e.g., in the +Z-axis direction) and move the lower bracket 13 downward (e.g., in the −Z-axis direction). The fact that the pressing force of the upper load cell LC1 is greater than the set range may indicate that the upper brush 14 is pressing the substrate W with an excessive intensity greater than pressing force within the set range. In this case, the controller may prevent or reduce excessive pressing applied to the substrate W by the brush, by increasing the distance between the upper bracket 12 and the lower bracket 13. When the detected pressing force of the upper load cell LC1 is less than the set range, the controller may move the upper bracket 12 and the lower bracket 13 closer to each other, i.e., move the upper bracket 12 downward and move the lower bracket 13 upward. The fact that the pressing force of the upper load cell LC1 is less than the set range may indicate that the upper brush 14 is applying less pressing force to the substrate W than the set range and that cleaning of the surface of the substrate W is not sufficiently being performed. In this case, the controller may decrease the distance between the upper bracket 12 and the lower bracket 13 so that the substrate W may be sufficiently pressed by the brush and cleaning of the surface of the substrate W may be sufficiently performed. As described above, the controller may increase efficiency of a substrate cleaning process by feedback-controlling the distance between the upper bracket 12 and the lower bracket 13 based on the information of the detected pressing force of the upper load cell LC1.

Hereinafter, a mechanism for detecting frictional force between the substrate W and the brush generated due to a rotation of the brush by the hinge portion 17, the lower load cell LC2, and the lower stopper S2 is described.

In an embodiment, the hinge portion 17 may be connected to the frame body 11a of the support frame 11. The hinge portion 17 may be provided in plurality. For example, each of the plurality of hinge portions 17 (e.g., a hinge portion 171 and a hinge portion 172) may be connected to the frame body 11a of each of the plurality of support frames 11 (e.g., the support frame 111 and the support frame 112). As the support frame 11 may be rotatably connected to the support structure 10, when the support frame 11 rotates in a first rotation direction R1 about the first axis X1 relative to the support structure 10, the hinge portion 17 may also rotate in the first rotation direction R1 together with the support frame 11. When the support frame 11 rotates in a second rotation direction R2 opposite to the first rotation direction R1 about the first axis X1, the hinge portion 17 may also rotate in the second rotation direction R2 together with the support frame 11. In an embodiment, the hinge portion 17 may include a hinge body 17a, and a first flange 17b and a second flange 17c extending in both directions from the hinge body 17a. The hinge body 17a may refer to a body of the hinge portion 17 connected to the frame body 11a of the support frame 11.

In an embodiment, the lower load cell LC2 may be arranged on the base B to be adjacent to the hinge portion 17. The lower load cell LC2 may be provided in plurality. Each of the plurality of lower load cells LC2 (e.g., a lower load cell LC21 and a lower load cell LC22) may be arranged on the base B to face each other. The lower load cell LC2 may be pressed by the first flange 17b of the hinge portion 17. For example, when the hinge portion 17 is rotated in the first rotation direction R1 by rotation of the support frame 11, the first flange 17b of the hinge portion 17 may press the lower load cell LC2. In this case, the lower load cell LC2 may detect pressing force applied by the first flange 17b. The lower load cell LC2 may transfer or transmit information regarding the detected pressing force of the first flange 17b to the controller described below.

In an embodiment, a torque detection portion (not shown) may detect a rotation torque of the rotation actuator 16. The torque detection portion may transfer or transmit information regarding the detected rotation torque of the rotation actuator 16 to the controller described below.

In an embodiment, the controller (not shown) may detect frictional force between the substrate W and the lower brush 15 based on information regarding the pressing force detected by the lower load cell LC2 and information regarding the rotation torque detected by the torque detection portion. For example, when a torque value of the rotation actuator 16 is [symbol] , the frictional force f_{f} between the substrate W and the lower brush 15 may be proportional to [symbol] . In an embodiment, when the pressing force of the first flange 17b detected by the lower load cell LC2 is F_{loadcell}, F_{loadcell} may be generated due to a reaction of the frictional force between the lower brush 15 and the substrate W. That is, F_{loadcell} and F_{f} may be proportional to each other. Thus, the controller may receive information regarding the torque value [symbol] of the rotation actuator 16 and the pressing force F_{loadcell} of the first flange 17b detected by the lower load cell LC2 and may detect a magnitude or a change pattern of F_{f} through [symbol] and F_{loadcell}. In addition, the controller may compare the frictional force F_{f} calculated using the torque value [symbol] of a rotation motor to a value of the pressing force F_{loadcell} of the first flange 17b detected by the lower load cell LC2 to analyze frictional characteristics between the lower brush 15 and the substrate W. For example, the controller may detect the magnitude of the frictional force between the lower brush 15 and the substrate W, and when the magnitude of the frictional force is greater than a set range, the controller may reduce the power of the rotation actuator 16 to reduce the frictional force between the brush and the substrate W, and when the magnitude of the frictional force is less than the set range, the controller may increase the power of the rotation actuator 16 to increase the frictional force between the brush and the substrate W. In addition, the controller may analyze a change in the magnitude of the frictional force between the lower brush 15 and the substrate W to analyze information regarding presence of foreign substances on the surface of the substrate W or roughness of the surface.

In an embodiment, the lower stopper S2 may be arranged on the base B to be adjacent to the hinge portion 17. The lower stopper S2 may be provided in plurality. For example, each of the plurality of lower stoppers S2 (e.g., a lower stopper S21 and a lower stopper S22) may be arranged on the base B to face each other. The lower stopper S2 may be pressed by the second flange 17c of the hinge portion 17. For example, when the hinge portion 17 is rotated in the second rotation direction R2 by rotation of the support frame 11, the second flange 17c of the hinge portion 17 may press the lower stopper S2. In this case, the lower stopper S2 may restrict a rotational motion of the second flange 17c that is to rotate in the second rotation direction R2. For example, the lower stopper S2 may be positioned at substantially the same height as a lower end surface of the second flange 17c of the hinge portion 17 based on the length in the height direction (e.g., the +Z-axis direction) with respect to the ground. That is, the lower stopper S2 may restrict the rotation of the second flange 17c of the hinge portion 17 in the second rotation direction R2, thereby restricting the rotation of the support frame 11, to which the hinge portion 17 is connected, in the second rotation direction R2. The lower stopper S2 may prevent or reduce a release of a substrate cleaning state, which may be induced by the support frame 11 rotating in the second rotation direction R2. The lower stopper S2 may ensure uniformity of substrate cleaning efficiency by maintaining the substrate cleaning state.

While the embodiments are described with reference to a limited number of drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or substituted by other components or their equivalents.

Therefore, other implementations, other embodiments, and equivalents to the claims are also within the scope of the following claims.

What is claimed is:

1. A substrate cleaning system comprising:
a base;
a plurality of support structures arranged in parallel with each other on the base;
a plurality of support frames connected to each of the plurality of support structures to be rotatable about a first axis and comprising a frame body and a guide rail formed on the frame body in a height direction;
a plurality of upper brackets connected to each of the plurality of support frames to be movable in the height direction along the guide rail;
a plurality of lower brackets arranged in a lower portion of the plurality of upper brackets, and connected to each of the plurality of support frames to be movable in the height direction along the guide rail;
an upper brush connected to the plurality of upper brackets to be rotatable about a first rotation axis parallel to the first axis, and configured to clean an upper surface of a substrate;
a lower brush connected to the plurality of lower brackets to be rotatable about a second rotation axis parallel to the first axis, and configured to clean a lower surface of the substrate;
a rotation actuator connected to the upper brush and the lower brush;
an upper load cell connected to an upper bracket;
an upper stopper connected to a frame body of a support frame to be positioned below the upper load cell;
a lower load cell arranged on the base; and
a hinge portion connected to the frame body of the support frame and configured to press the lower load cell when the support frame rotates in a first rotation direction.

2. The substrate cleaning system of claim 1, wherein the upper load cell is configured to:
contact the upper stopper and detect pressing force applied by the upper stopper when an upper bracket moves downward on the guide rail along the height direction.

3. The substrate cleaning system of claim 2, further comprising:
a controller,
wherein the controller is configured to, based on information regarding the detected pressing force of the upper load cell:
move the upper bracket and a lower bracket away from each other when the pressing force is greater than a set range; and
move the upper bracket and the lower bracket toward each other when the pressing force is less than the set range.

4. The substrate cleaning system of claim 1, further comprising:
a lower stopper arranged in the base so that the lower stopper is configured to contact the hinge portion when the support frame rotates in a second rotation direction, which is opposite to the first rotation direction.

5. The substrate cleaning system of claim 4, wherein the hinge portion comprises:
a hinge body connected to the frame body;
a first flange extending from the hinge body and configured to press the lower load cell; and
a second flange extending from the hinge body and configured to press the lower stopper.

6. The substrate cleaning system of claim 5, wherein the lower load cell is configured to:
detect pressing force applied by the first flange of the hinge portion when the support frame rotates in the first rotation direction.

7. The substrate cleaning system of claim 6, further comprising:
a torque detection portion configured to detect a rotation torque of the rotation actuator; and
a controller,
wherein the controller is configured to:
detect frictional force between the substrate and the lower brush based on information regarding the pressing force detected by the lower load cell and information regarding the rotation torque detected by the torque detection portion; and
control an operation of the rotation actuator based on information regarding the detected frictional force.

8. The substrate cleaning system of claim 1, wherein the upper bracket comprises:
a first upper bracket portion connected to the upper brush;
a second upper bracket portion extending from the first upper bracket portion and connected to the support frame; and
a third upper bracket portion extending from the second upper bracket portion and connected to the upper load cell.

9. The substrate cleaning system of claim 1, wherein the lower bracket comprises:
a first lower bracket portion connected to the lower brush; and
a second lower bracket portion extending from the first lower bracket and connected to the support frame.
